(19) United States
(12) Patent Application Publication
(10) Pub. No.: US 2009/0090942 A1
(43) Pub. Date: Apr. 9, 2009

(54) Wiring structure, array substrate, display device having the same and method of manufacturing the same

(75) Inventors: Kyong-Sub Kim, Suwon-si (KR); Sang-Un Nam, Cheonan-si (KR); Chang-Oh Jeong, Suwon-si (KR); Weon-Sik Oh, Suwon-si (KR); Sung-Lak Choi, Osan-si (KR); Soo-Im Jeong, Suwon-si (KR); Jae-Ho Eo, Cheonan-si (KR)

Correspondence Address: MACPHERSON KWOK CHEN & HEID LLP, 2033 GATEWAY PLACE, SUITE 400, SAN JOSE, CA, 95110, US

(73) Assignee: SAMSUNG ELECTRONICS CO. LTD.

(21) Appl. No.: 12/231,709

(22) Filed: Sep. 4, 2008

(30) Foreign Application Priority Data
Sep. 4, 2007 (KR) 10-2007-0089554

(51) Int. Cl. H01L 29/786; H01B 5/14; B05D 5/12; H01L 21/336

(52) U.S. Cl. 257/288; 174/126.2; 427/123; 438/158; 257/E29.273; 257/E21.411

(57) ABSTRACT

A wiring structure includes a substrate, a copper oxide layer having 16˜39 at % oxygen on the substrate and a copper layer on the copper oxide layer. The copper oxide layer has a thickness of 10-1000 Å and the copper layer has a thickness of 300-8000 Å. The copper layer and the copper oxide layer further have an alloy element less than 10 wt % and the alloy element is selected from the group of Ag, Ni, Mg, Zr, N.

### CROSS-REFERENCE TO RELATED APPLICATIONS

The present application claims priority from and the benefit of Korean Patent Application No. 2007-59554, filed on Sep. 4, 2007, the disclosure of which is hereby incorporated by reference for all purposes as if fully set forth herein.

### BACKGROUND OF THE INVENTION

1. Field of the Invention

The present invention relates to a wiring structure, an array substrate, a display device including the array substrate, and a method of manufacturing the array substrate. More particularly, the present invention relates to an array substrate capable of decreasing line resistance and the occurrence of line defects, a display device including the array substrate, and a simplified method of manufacturing the array substrate.

2. Discussion of the Background

An array substrate of a flat panel display device includes various lines for transmitting signals, which are formed through a thin film deposition processes.

There is an increasing need for larger screen flat panel display devices and high quality flat panel display devices. One way to accomplish these goals is to use metal lines having low resistivity for high frequency driving circuits. Au, Ag, Cu, Al, etc. are metals having low resistivity. Au and Ag are too expensive to use for flat panel displays. Al is most widely used for flat panel displays, but nowadays the market needs a metal having a lower resistivity than Al, for example, Cu and Ag. Al, Cr, and Mo have enough adhesion to make a wire on the substrate, but compared with other metals, Cu has very weak adhesion with the substrate. To solve this problem, another metal which is not Cu is disposed between the substrate and the Cu layer. But this causes an undercut in the wet etching process or requires an additional dry etching process to etch the other layer.

### SUMMARY OF THE INVENTION

The present invention provides a wire structure capable of decreasing line resistance and the occurrence of line defects. In one embodiment of the invention, a process using a Cu or Cu alloy on the substrate for increasing the adhesion of the Cu layer without using another additional metal layer is used. This process can be a very cheap and simple process.

The present invention also provides an array substrate including the above mentioned array substrate.

The present invention also provides a display device including the above mentioned array substrate.

The present invention also provides a simplified method of manufacturing the array substrate.

The present invention discloses a wiring structure including a substrate, a copper oxide layer having 16˜39 at % oxygen on the substrate and a copper layer on the copper oxide layer. The copper oxide layer has a thickness of 10-1000 Å and the copper layer has a thickness of 300-20000 Å. The copper layer and the copper oxide layer further have an alloy element less than 10 wt % and the alloy element is selected from the group of Ag, Ni, Mg, Zr, and N.

The present invention also discloses a method of manufacturing a wiring structure that is provided as follows. A copper oxide layer having 16˜39 at % oxygen is formed on the substrate. A copper layer is formed on the copper oxide layer. The copper oxide layer has a thickness of 10-1000 Å. The copper layer has a thickness of 300-20000 Å. The copper layer and the copper oxide layer further have an alloy element less than 10 wt %. The alloy element is selected from the group of Ag, Ni, Mg, Zr, and N.

The present invention also discloses a thin film transistor including a gate electrode having a copper layer and copper oxide layer on an insulating substrate, a semiconductor layer on the gate electrode and a source and drain electrode on the semiconductor layer. The copper oxide layer has an 16 at % 39 at % oxygen. The thickness of the copper oxide layer is 10-1000 Å. The copper layer has a thickness of 300-20000 Å. The copper layer and the copper oxide layer further have an alloy element less than 10 wt %. The alloy element is selected from the group of Ag, Ni, Mg, Zr, and N.

The present invention also discloses a method of manufacturing a thin film transistor that is provided as follows. A gate electrode with a copper layer and copper oxide layer is formed. A semiconductor layer is formed on the gate electrode and a source and drain electrode is formed on the semiconductor layer. The copper oxide layer has a 16 at %˜39 at % oxygen. The thickness of the copper oxide layer is 10-1000 Å. The copper layer has a thickness of 300-20000 Å. The copper layer and the copper oxide layer further have an alloy element less than 10 wt %. The alloy element is selected from the group of Ag, Ni, Mg, Zr, and N.

It is to be understood that both the foregoing and general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention. The patent or application file contains at least one drawing executed in color. Copies of this patent or patent application publication with color drawings will be provided by the U.S. Patent and Trademark Office upon request and payment of the necessary fee.

FIG. 1 is a cross-sectional view of the wiring structure according to one embodiment of the invention.

FIG. 2 is a detailed cross-sectional view of the wiring structure of FIG. 1.

FIG. 3 to 5 is a photograph of the adhesion result of the copper layers.

FIG. 6 is a graph of the adhesion of the various metal layers.

FIGS. 7a, 7b, 7c are photographs of each back side of the same samples of FIG. 3 to 5.

FIG. 8 is an adhesion graph of a copper layer according to the oxygen fraction of the copper oxide layer.

FIG. 9 is a plan view showing an array substrate in accordance with one exemplary embodiment of the present invention.

FIG. 10 is a cross-sectional view taken along line I-I′ of FIG. 1.

FIG. 11 is a cross-sectional view taken along line II-II′ of FIG. 1.

FIG. 12 to FIG. 20 are cross-sectional views showing a method of manufacturing the array substrate of FIG. 10.

FIG. 21 is a cross-sectional view showing a display device in accordance with another exemplary embodiment of the present invention.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on,” “connected to” or “coupled to” another element or layer, it can be directly on, directly connected to, or directly coupled to the other element or layer, or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be described in detail with reference to the accompanying drawings.

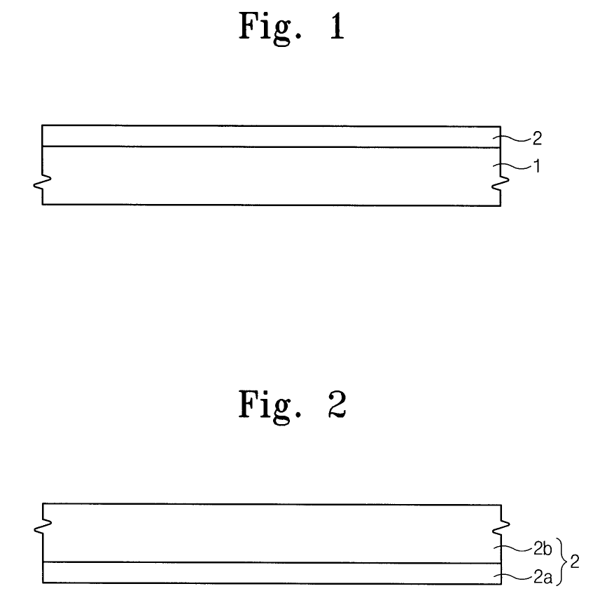

FIG. 1 illustrates a cross-section of a thin film 2 on a substrate 1. The structure of FIG. 2 is a detailed cross-section of a thin film wiring structure, having a copper layer 2b over a copper oxide 2a on a substrate 1. Copper oxide layer 2a is sputtered using a copper target with argon and oxygen in the vacuum chamber. When oxygen is not supplied to the chamber, the copper layer 2b is obtained. In this embodiment, a 300 Å copper oxide layer 3 is formed, and a 3000 Å copper layer 2 is formed over the copper oxide layer 3 on the substrate 1. In this embodiment of the invention sputtering is used, but electroplating, electroless plating, evaporation, chemical vapor deposition, etc. may be used for making a copper layer. The substrate 1 is a transparent or opaque material made of glass, plastic, etc.

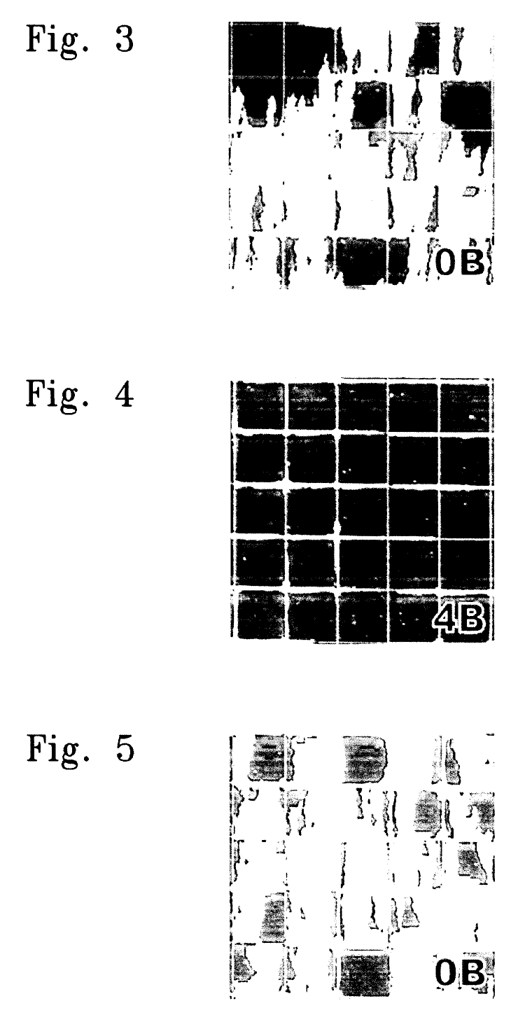

FIGS. 3 to 5 illustrate an adhesion result of the various thin films on the substrate.

FIG. 3 is the adhesion result of the FIG. 1 sample having only the copper layer 2 on the substrate 1. An ASTM D3359 method was used for the adhesion test. ASTM is a kind of measuring method for testing adhesion properties of a thin film which includes cutting the thin film on the substrate into a lattice pattern, attaching a sticky tape, and then taking off the tape. The dark areas represent areas where the copper layer remains on the substrate, and the light areas represent where the copper layer was removed by the sticky tape. If there is more thin film debris on the sticky tape after taking off the tape and the substrate is more exposed, the thin films have weaker adhesion properties. On the other hand, if more of the thin film remains on the substrate, the thin film has stronger adhesion properties. On the basis of the lattice area of the thin film, the remaining area of thin film may be calculated. (area remained=overall lattice area−removal area) When all the lattice area remains, none of the film is taken off, the adhesion is referred to as having an adhesion of 5B. When less than 5% of the thin film is taken off, the adhesion is referred to as having an adhesion of 4B. When 5% to 15% of the thin film is taken off, the adhesion is referred to as having an adhesion of 3B. When 15% to 35% of the thin film is taken off, the adhesion is referred to as having an adhesion of 2B. When 35% to 65% of the thin film is taken off, the adhesion is referred to as having an adhesion of 1B. When greater than 65% of the thin film is taken off, the adhesion is referred to as having an adhesion of 0B. The larger the adhesion, the stronger adhesion of the thin film to the substrate. In this way, we can test the adhesion of the thin film and rate the thin film.

The copper layer on the substrate illustrated in FIG. 3 has a 0B adhesion because of the large amount of light areas which remains indicating that most of the copper layer on the substrate was taken off. This shows the thin film of the copper layer on the substrate cannot be used for wiring because of its low adhesion to the substrate.

FIG. 4 shows the adhesion 4B of the copper layer over the copper oxide layer which has about 16 at %˜about 39 at % oxygen. Compared to FIG. 3, FIG. 4 shows very great adhesion to the substrate. The copper oxide layer, which has about 16 at % about 39 at % oxygen, adheres to the substrate like an adhesive. Making this copper oxide layer is a very simple and economic process. For example, in the sputtering method, just inputting the oxygen with argon can make the copper oxide layer on the substrate in the chamber and then preventing the oxygen from escaping will allow the copper layer to adhere to the copper oxide layer. FIG. 5 shows an adhesion of 0B of the copper layer over the copper oxide layer which has over 50 at % oxygen. Most of the copper layer of FIG. 5 is taken off as illustrated in FIG. 3. With this poor, 0B, adhesion, this wiring structure, cannot be used.

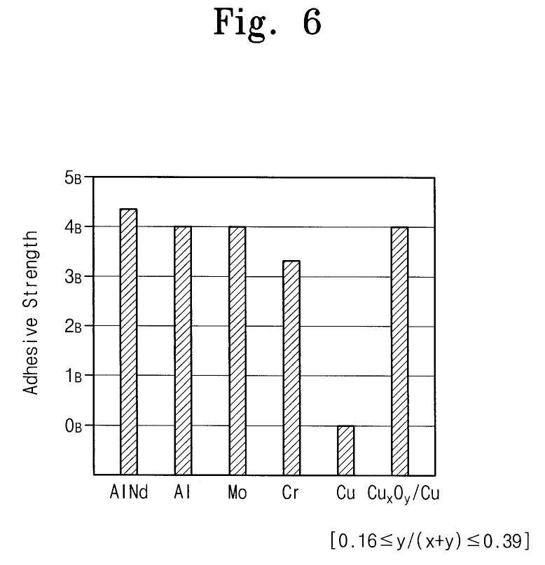

In FIG. 6, the adhesion of the various metal thin films is provided in order to compare the results from FIGS. 3, 4, and 5.

Referring to FIG. 6, Al, AlNd, Mo, Cr, which are often used as thin films, show more than 3B. But copper (Cu) shows OB which indicates very low adhesion. Thus it is very difficult to use copper as wiring on the substrate. Contrary to above result, the copper layer over the copper oxide layer having about 16 at %˜about 39 at % oxygen shows 4B adhesion which is enough to be used as a wiring. A copper oxide layer having 16 at %˜about 39 at % oxygen is CuₓO_{y}, wherein x and y is 0.16<{y/(x+y)}<0.39.

Copper oxide has two stable phases, one is Cu₂O and the other is CuO. When the copper is ionized Cu+, cuprous oxide Cu₂O is formed, and when the copper is ionized Cu++, cupric oxide CuO is formed. Cu₂O is reddish or brown and CuO is dark or grey.

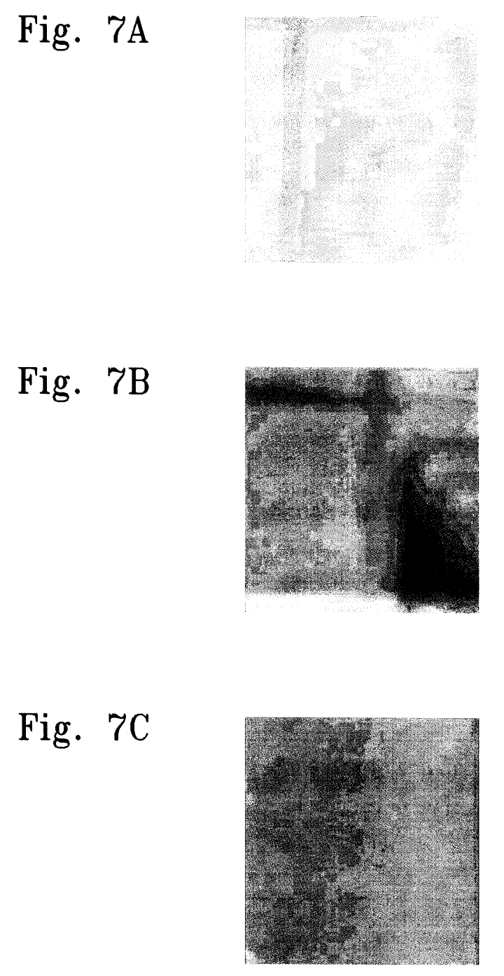

In FIGS. 7a, 7b, 7c, the photographs of each back side of the above FIGS. 3, 4, 5 samples are provided. Referring to FIG. 7a, a brown (brass) color is shown. The brown color is of the single copper layer on the transparent substrate. The copper oxide layer having 16 at %˜about 39 at % oxygen makes the copper layer adhere to the substrate, and shows a reddish color as shown in FIG. 7b. The light gray or light black line in FIGS. 7a and 7b are a reflected image of the ceiling of the laboratory. The surface of the back side of the sample in FIGS. 7a and 7b reflects like a mirror as other metal surfaces do. The copper layer having more than 50 at % oxygen, which is larger than the above ranges, shows a gray color as illustrated in FIG. 7c. The upper surface of the above sample is a copper layer, but the back side of the 7b and 7c samples shows the color of the copper oxide on the transparent substrate. Thus the oxygen fraction of the copper oxide adhesion layer, is recognized by its color. By the color of the copper oxide layer the adhesion can be guessed. For example, in the factory process, a copper oxide layer is formed on the substrate and a copper layer is formed on the copper oxide layer. Next, by inspecting the back side of the substrate, just looking at what the color is, we can distinguish the fraction of the copper oxide layer. Without other testing equipment, we can visually inspect samples. This is a simple, economic and convenient inspecting method.

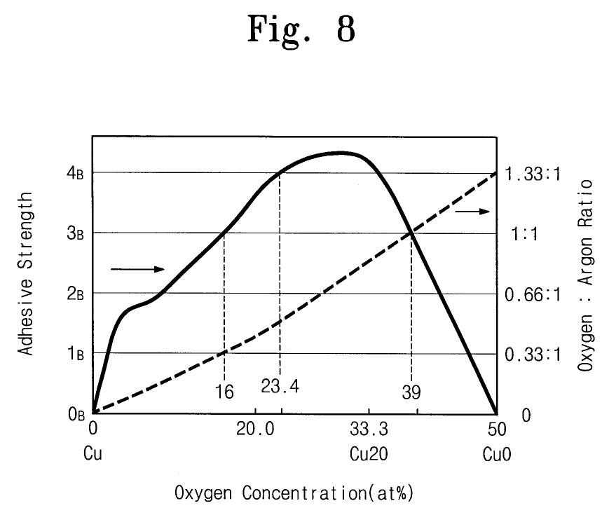

FIG. 8 illustrates the adhesion of the copper layer according to the oxygen fraction of the copper oxide layer.

Referring to FIG. 8, the adhesion of the copper oxide on the substrate is increased according to the increase of the oxygen fraction of the copper oxide layer. The adhesion increases to a peak adhesion, and then decreases. When the oxygen fraction is 16 at %, the adhesion of the copper oxide layer is 3B and when the oxygen fraction is around 30 at %, the maximum adhesion 4B is taken. The more oxygen over 30 at % in the copper oxide layer, the less the adhesion as is shown in FIG. 8. Herein the copper oxide layer is formed by a sputtering method while controlling the fraction of argon and oxygen. According to the increase in the oxygen fraction in the sputter chamber, the oxygen fraction of the copper oxide layer is also increased. If a partial pressure of argon is 1 and a partial pressure of oxygen is 0.33˜1, the copper thin film having a 3B adhesion is formed. In this embodiment, a sputtering method is used for the thin film, but any other method, for example, electro plating, electroless plating, chemical vapor deposition, evaporation, and etc. can be also used.

There are a variety of methods to form a copper oxide layer. The first way is using a reactive sputtering method as explained above. During the sputtering, the oxygen fraction is controlled and introduced to the sputtering chamber for forming a copper oxide (CuₓO_{y}, 0.16<{y/(x+y)}<0.39) layer. The second way is 1) forming a copper layer or copper oxide layer on the substrate and 2) heating them to contain 16˜39 at % oxygen in the copper oxygen layer. The heating temperature is about 220˜400° C., and the heating time is different according to the films.

The thin film transistor substrate and display device which is formed in relation to the thin film structure as discussed above will now be explained.

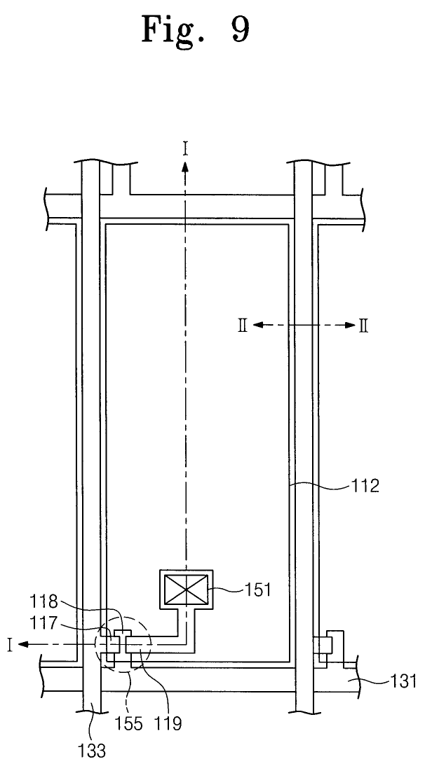

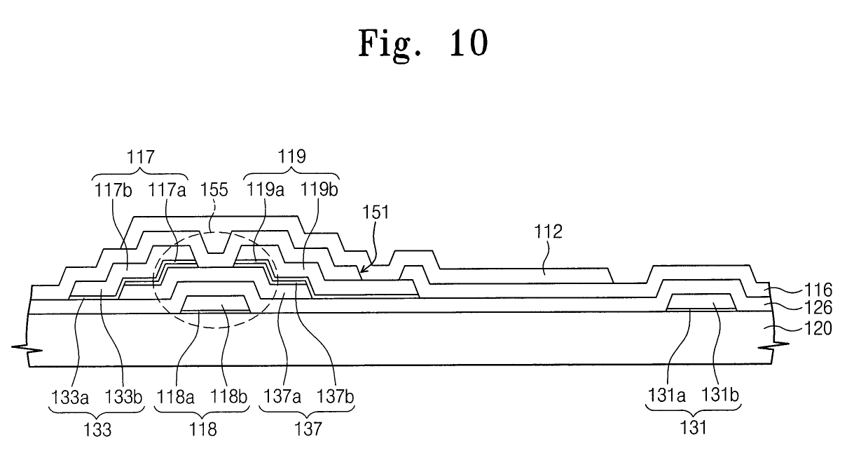

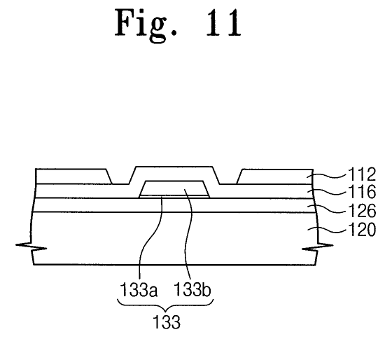

FIG. 9 is a plan view showing an array substrate in accordance with one exemplary embodiment of the present invention. FIG. 10 is a cross-sectional view taken along line I-I′ of FIG. 1. FIG. 11 is a cross-sectional view taken along line II-II′ of FIG. 1.

Referring to FIG. 10, the array substrate includes an insulating substrate 120, a gate line 131, a data line 133, a gate insulating layer 126, a passivation layer 116, a pixel electrode 112 etc. Alternatively, the array substrate may include a plurality of gate lines, a plurality of data lines, and a plurality of pixel electrodes.

The insulating substrate 120 may include a transparent glass that transmits light.

The insulating substrate 120 may also include a high polymer that is optically transparent. Examples of optically transparent high polymers that may be included in the insulating substrate 120 include triacetylcellulose (TAC), polycarbonate (PC), polyethersulfone (PES), polyethyleneterephthalate (PET), polyethylenenaphthalate (PEN), polyvinylalcohol (PVA), polymethylmethacrylate (PMMA), cyclo-olefin polymer (COP), and combinations thereof.

The gate line 131 is disposed on the insulating substrate 120. The gate line 131 includes a gate adhesion layer 131a, a gate conductive layer 131b.

The gate adhesion layer 131a is disposed on the insulating substrate 120. The gate adhesion layer 131a increases the adhesive strength between the gate line 131 and the insulating substrate 120. Examples of an adhesion material that may be used in the gate adhesion layer 131a include a copper oxide layer and copper alloy oxide layer. The fraction of the copper oxide layer is about 16 at % about 39 at %. This fraction of oxygen allows the copper oxide to adhere to the substrate and prevents the film from lifting or peeling. This strong adhesion does not cause any other problems in subsequent processes like etching, washing, stripping process, etc.

The gate conductive layer 131b is disposed on the gate adhesion layer 131a. The gate conductive layer 131b may include copper or a copper alloy. When the gate conductive layer 131b includes copper, the resistance of the gate conductive layer 131b is about 2.1 μΩcm to about 2.3 μΩcm. Thus, the resistance of the gate conductive layer 131b is about 30% smaller than that of an aluminum layer, which has a resistance of about 3.1 μΩcm. In addition, the gate conductive layer 131b has lower electro-migration than an aluminum layer.

A gate electrode 118 of the thin film transistor 155 is disposed on the insulating substrate 120. The gate electrode 118 may include a copper or copper alloy. The gate electrode 118 may be formed on substantially the same layer as the gate line 131. The gate electrode 118 includes a gate adhesion pattern 118a, and a gate conductive pattern 118b.

The gate adhesion pattern 118a is disposed on the insulating substrate 120. The gate adhesion pattern 118a may include substantially the same material as the gate adhesion layer 131a of the gate line 131.

The gate conductive pattern 118b is disposed on the gate adhesion pattern 118a. The gate conductive pattern 118b may include a copper or copper alloy. For example, the gate conductive pattern 118b may include substantially the same material as the gate conductive layer 131b of the gate line 131.

The gate insulating layer 126 is disposed on the insulating substrate 120 to cover the gate line 131 and the gate electrode 118.

The gate insulating layer 126 may be formed through a chemical vapor deposition (CVD) method using silane gas and a nitride mixture gas. The chemical vapor deposition method may be a plasma enhanced chemical vapor deposition (PECVD) method. The nitride mixture gas may contain nitrogen (N₂) gas, ammonia (NH₃) gas, and combinations thereof.

The semiconductor pattern 137 of the thin film transistor 155 is disposed on the gate insulating layer 126 corresponding to the gate electrode 118. The semiconductor pattern 137 includes the amorphous silicon pattern 137a and an n+ amorphous silicon pattern 137b which is an ohmic contact layer.

When an electric field is applied between the gate electrode 118 and the source electrode 117, a channel is formed in the lower amorphous silicon pattern adjacent to the gate insulating layer 126.

The n+ amorphous silicon pattern 137b includes a first pattern and a second pattern. The first and second patterns are spaced apart from each other on the amorphous silicon pattern 137a.

The data line 133 is disposed on the gate insulating layer 126. The data line 133 includes a data barrier layer 133a and a data conductive layer 133b.

The data barrier layer 133a is on the gate insulating layer 126, the amorphous silicon pattern 137a, and the n+ amorphous silicon pattern 137b. The data barrier layer 133a prevents the silicon atoms of the amorphous silicon layer from diffusing into the data conductive layer 133b, which may prevent the resistance of the data conductive layer 133b from increasing. Examples of a conductive material that may be included in the data barrier layer 133a include molybdenum (Mo), Titanium (Ti), Tantalum (Ta), Tungsten (W), molybdenum-titanium (Mo—Ti) alloy, molybdenum-tungsten (Mo—W) alloy, molybdenum-chromium (Mo—Cr) alloy, molybdenum-niobium (Mo—Nb) alloy, and combinations thereof.

The data conductive layer 133b is disposed on the data barrier layer 133a. The data conductive layer 133b may include a copper or copper alloy. For example, the data conductive layer 133b may include substantially the same material as the gate conductive layer 131b. Thus, any further explanation concerning the above elements will be omitted. In this embodiment, the data line includes two layers (a barrier layer and conductive layer) but the data line may include 3 layers such as a barrier layer, conductive layer, capping layer. And a single layer like a copper alloy layer or copper layer which also can be used as a data line. The data line may also comprise a copper oxide layer having about 16 at %˜about 39 at % oxygen fraction.

A source electrode 117 of the thin film transistor 155 is disposed on a first pattern of the n+ amorphous silicon pattern. The source electrode 117 may include a copper or copper alloy. The source electrode 117 may be formed on substantially the same layer as the data line 133. The source electrode 117 is connected to the data line 133 and includes a source barrier pattern 117a and a source conductive pattern 117b.

The source barrier pattern 117a is disposed on the first pattern of the n+ amorphous silicon pattern. The source barrier pattern 117a may include a conductive material such as molybdenum (Mo), Titanium (Ti), Tantalum (Ta), Tungsten (W), molybdenum-titanium (Mo—Ti) alloy, molybdenum-tungsten (Mo—W) alloy, molybdenum-chromium (Mo—Cr) alloy, molybdenum-niobium (Mo—Nb) alloy, and combinations thereof. For example, the source barrier pattern 117a may include substantially the same material as the data barrier layer 133a of the data line 133.

The source conductive pattern 117b is disposed on the source barrier pattern 117a. The source conductive pattern 117b may include a copper or copper alloy. For example, the source conductive pattern 117b may include substantially the same material as the data conductive layer 133b of the data line 133.

A drain electrode 119 of the thin film transistor 155 is disposed on a second pattern of the n+ amorphous silicon pattern. The drain electrode 119 may include copper or a copper alloy. For example, the drain electrode 119 may be formed from substantially the same layer as the data line 133. The drain electrode 119 is electrically connected to the pixel electrode 112 and includes a drain barrier pattern 119a and a drain conductive pattern 119b.

The drain barrier pattern 119a is on the second pattern of the n+ amorphous silicon pattern. The drain adhesion pattern 119a may include substantially the same material as the data adhesion layer 133a of the data line 133.

The drain conductive pattern 119b is disposed on the drain adhesion pattern 119a. The drain conductive pattern 119b may include copper or a copper alloy. For example, the drain conductive pattern 119b may include substantially the same material as the data conductive layer 133b of the data line 133.

The passivation layer 116 is disposed on the gate insulating layer 126 to cover the semiconductor pattern 137, the data line 133, the source electrode 117, and the drain electrode 119. The passivation layer 116 may include silicon nitride. Alternatively, the passivation layer 116 may have a double layered structure including a low density silicon nitride layer and a high density silicon nitride layer. The passivation layer 116 may include an organic layer and a double layer including an organic layer and an inorganic layer. The passivation layer 116 may have a contact hole 151 through which the drain electrode 119 is partially exposed.

The pixel electrode 112 is disposed on the passivation layer 116 and is connected to the drain electrode 119 through the contact hole 151. The pixel electrode 112 may include a transparent conductive material. Examples of the transparent conductive material that may be included in the pixel electrode 112 include indium tin oxide (ITO), indium zinc oxide (IZO), amorphous indium tin oxide (a-ITO), and combinations thereof.

According to this embodiment, the copper oxide layer as a adhesion layer which has about 16 at %˜30 at % oxygen fraction allowing the copper layer to adhere to the substrate 120. Thus the copper layer and the substrate can be utilized in subsequent processes. For instance the copper layer can also be used for wiring through this simple process.

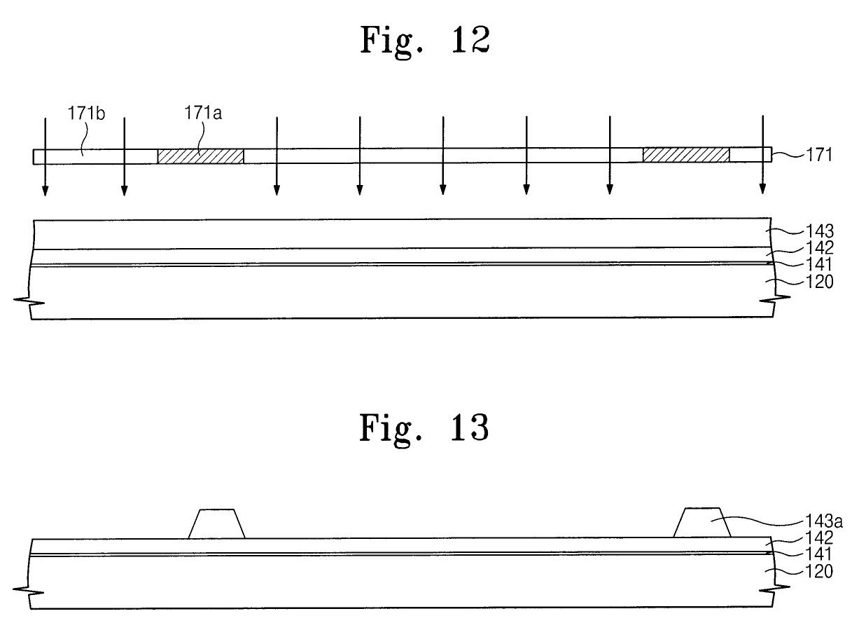

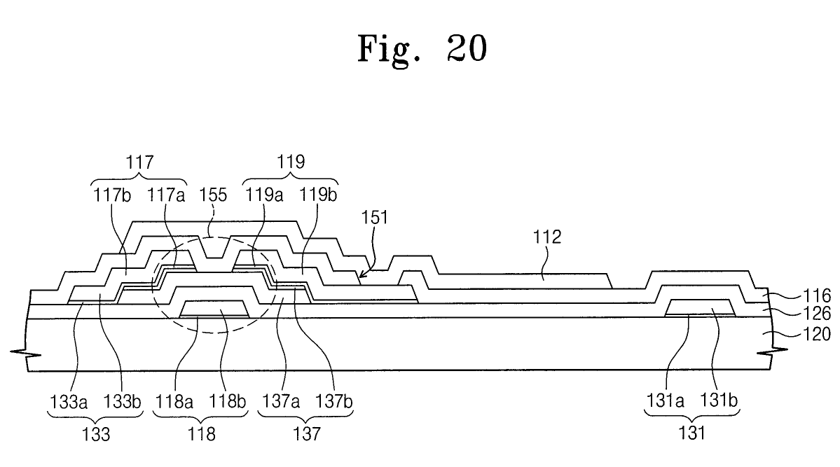

FIG. 12 to FIG. 20 are cross-sectional views showing a method of manufacturing the array substrate shown in FIG. 10.

Referring to FIG. 12 and FIG. 15, a gate adhesion layer 141 and a gate conductive layer 142 are formed on the insulating substrate 120, in sequence. A gate adhesion layer 141 and gate conductive layer 142 is formed in a single sputtering chamber or in a single sputtering apparatus. A sputtering target of copper is set in the chamber, and argon and oxygen gas is injected. The copper oxide layer is deposited to the substrate. The partial pressure of the oxygen to argon is recommended to be about 0.33:1 to 1:1. In this atmosphere, the deposited copper oxide layer contains about 16 at % to 39 at % oxygen. The copper oxide layer formed in this way is a gate adhesion layer 141. Then the oxygen gas is not injected to the chamber and the copper target is sputtered. The deposited copper layer is the gate conductive layer 142. In this embodiment, 300□ copper oxide is formed, and the 3000% copper layer is formed on the copper oxide layer which is the gate adhesion layer and the gate conductive layer. In a single chamber, a gate adhesion layer and the gate conductive layer are formed just by controlling a gas injection, so the process is simpler and the cost is decreased.

The copper oxide layer as a gate adhesion layer is formed by the sputtering method described above, but the copper oxide can also be formed by another method. For example, a heating method is used after forming a copper layer. An oxygen fraction that is not provided above is injected to the chamber, then the layer is heated to contain a oxygen fraction of 16 at % to 39 at %.

The thickness of the copper oxide may be about 10□ to 1000□. And the copper layer may have a thickness of about 300□ to 20000□.

Moreover, the copper layer and the copper oxide layer further comprise less than al 0% alloying element selected from a group of Ag, Ni, Mg, Zr, and N.

A gate photoresist film 143 is coated on the gate conductive layer 142.

The gate photoresist film 143 is exposed through a gate mask 171. The gate mask 171 includes a light blocking portion 171a and a transparent portion 171b. The light blocking portion 171a corresponds to the gate line 131 and the gate electrode 118.

As illustrated in FIG. 13, the exposed gate photoresist film 143 is developed to form a gate photoresist pattern 143a on the gate conductive layer 142.

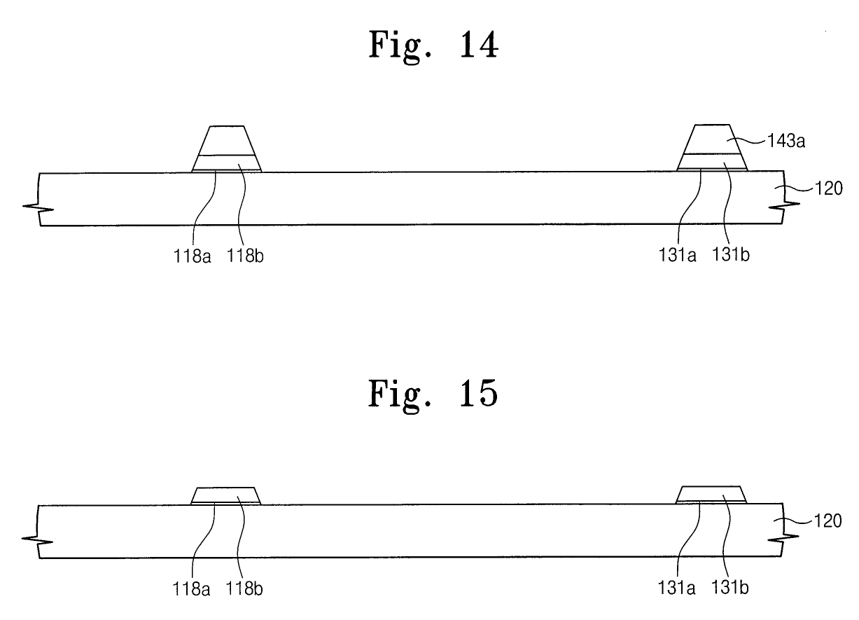

The gate conductive layer 142 and the gate adhesion layer 141 are partially etched as illustrated in FIG. 14, using the gate photoresist pattern 143a as an etching mask, to form the gate adhesion layer 131a, a gate conductive layer 131b, the gate adhesion pattern 118a, and a gate conductive pattern 118b on the insulating substrate 120. The gate photoresist pattern 143a is then removed, as illustrated in FIG. 15, from the gate conductive layer 131b and the gate conductive pattern 118b.

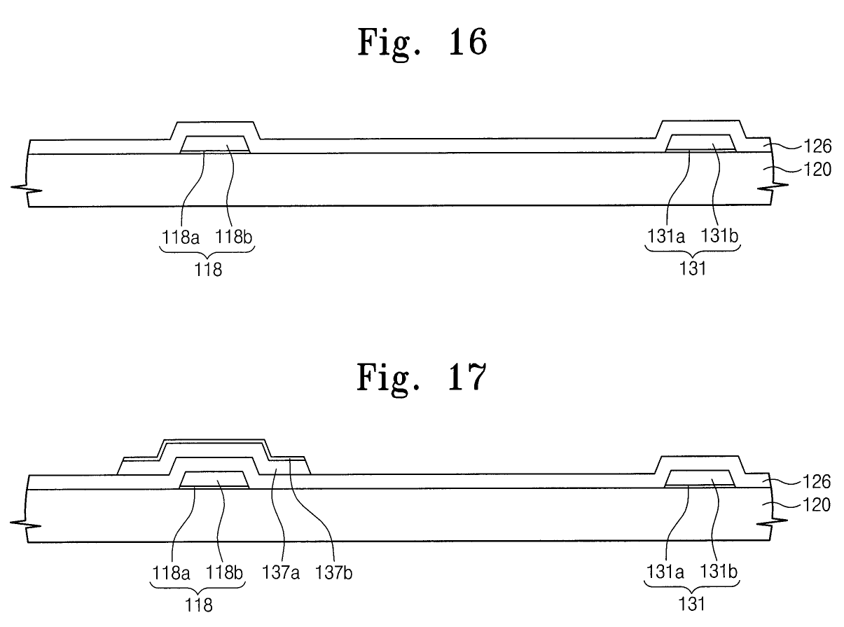

A gas mixture, including silane gas and a nitrogen mixture gas, may be injected onto the insulating substrate 120, on which the gate electrode 118, the gate line 131, and the gate insulating layer 126 (shown in FIG. 16) are formed, through a chemical vapor deposition (CVD) method. Examples of the nitrogen mixture gas that may be injected onto the insulating substrate 120 include nitrogen gas, ammonia gas, and combinations thereof. The chemical vapor deposition method may be a plasma enhanced chemical vapor deposition (PECVD) method. The gate insulating layer 126 may be formed with an organic material.

Referring to FIG. 17, an amorphous silicon layer is deposited on the gate insulating layer 126. Then, n+ impurities are implanted into an upper portion of the amorphous silicon layer to form an n+ amorphous silicon layer (not shown).

The n+ amorphous silicon layer and the amorphous silicon layer are partially etched to form a n+ amorphous silicon pattern 137c and the amorphous silicon pattern 137a.

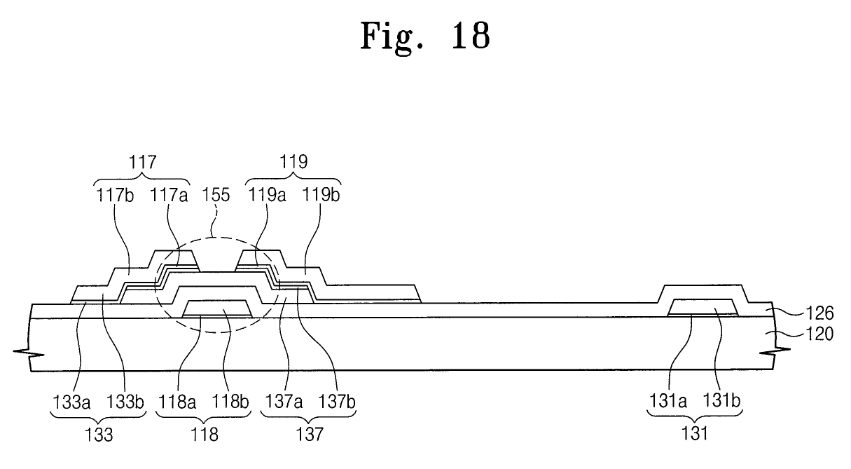

Referring to FIG. 18, a data barrier layer (not shown) and a data conductive layer (not shown) are formed on the gate insulating layer 126, in sequence. A data photoresist film (not shown) is formed on the primary data conductive layer.

The data barrier layer and the data conductive layer are partially etched through a photolithography process using a data mask (not shown) to form the data barrier layer 133a, a data conductive layer 133b, the source barrier pattern 117a, a source conductive pattern 117b, the drain barrier pattern 119a, and a drain conductive pattern 119b.

Referring to FIG. 18, the n+ amorphous silicon pattern 137c interposed between the source electrode 117 and the drain electrode 119 is partially etched, using the source electrode 117 and the drain electrode 119 as an etching mask, to form the semiconductor pattern 137 including the n+ amorphous silicon pattern 137b and the amorphous silicon pattern 137a.

In FIG. 17, and FIG. 18, the semiconductor pattern 137, the data line 133, the source electrode 117, and the drain electrode 119 are formed using two photo masks. Alternatively, the semiconductor pattern, the data line, the source electrode, and the drain electrode may be formed using one photo mask.

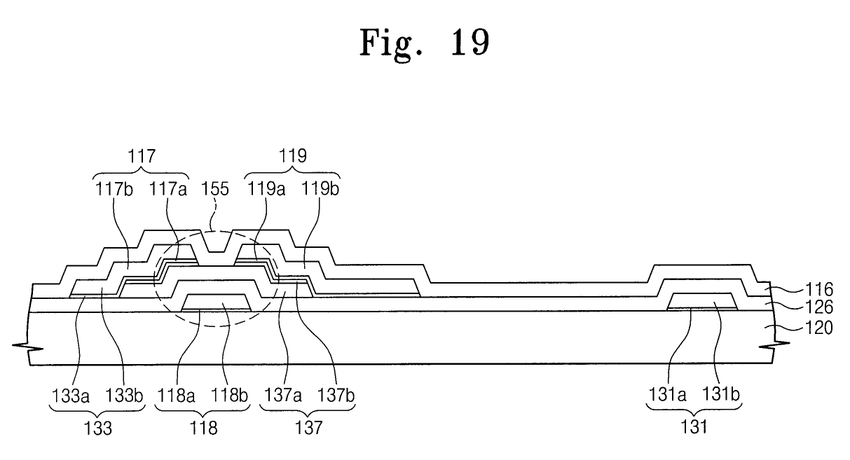

Referring to FIG. 19, the passivation layer 116 is formed on the gate insulating layer 126 to cover the semiconductor pattern 137, the data line 133, the source electrode 117, and the drain electrode 119. For example, silane gas and the nitrogen mixture gas may be injected onto the gate insulating layer 126, and the passivation layer 116 may be formed on the gate insulating layer 126 by a chemical vapor deposition (CVD) method. The passivation layer may be formed with an organic material. The passivation layer 116 may include a first passivation layer (not shown) and a second passivation layer (not shown). The second passivation layer may be disposed on the first passivation layer. For example, the passivation layer includes an organic layer on the silicon nitride layer.

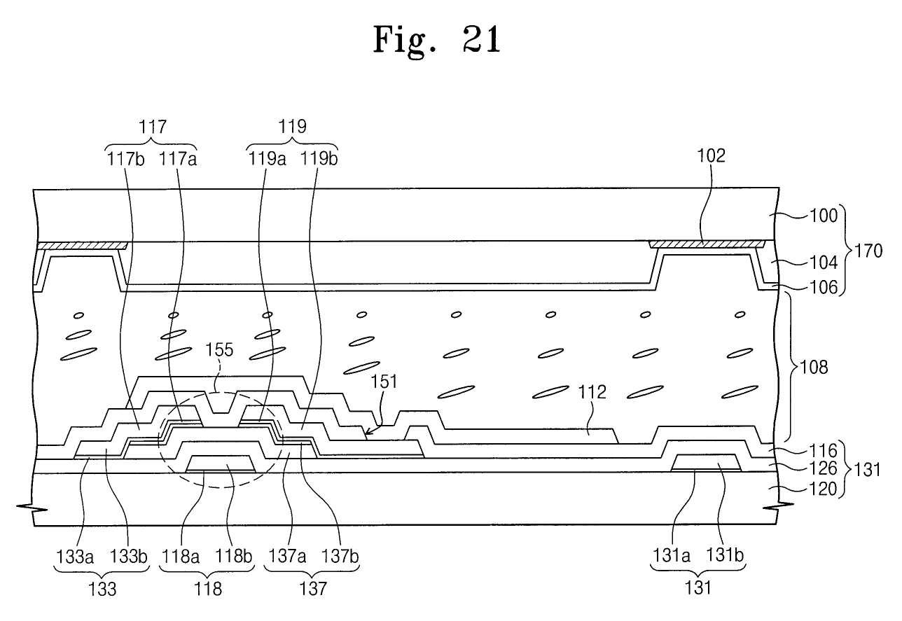

Referring to FIG. 21, the passivation layer 116 may be partially etched to form the contact hole 151 through which the drain electrode 119 is partially exposed. Alternatively, a laser beam may be irradiated onto the pixel electrode 112 corresponding to the drain electrode 119 to form the contact hole 151 after the pixel electrode 112 is formed.

The pixel electrode 112 connected to the drain electrode 119 is formed on the passivation layer 116 and the contact hole 151 formed in the passivation layer 116.

FIG. 21 is a cross-sectional view showing a display device in accordance with another exemplary embodiment of the present invention.

Referring to FIG. 21, the display device includes an array substrate 180, an opposite substrate 170, and a liquid crystal layer 108. The array substrate 180 of FIG. 21 is the same as that of FIG. 9 to FIG. 11. Thus, the same reference numerals will be used to refer to the same or like parts and any further explanation concerning the above elements will be omitted.

The opposite substrate 170 includes an opposite insulating substrate 100, a black matrix 102, a color filter 104, and a common electrode 106. The opposite substrate 170 may further include a plurality of color filters.

The opposite insulating substrate 100 includes a transparent insulating material. Examples of the transparent insulating material that may be included in the opposite insulating substrate 100 include glass, quartz, and synthetic resin. For example, the opposite insulating substrate 100 may include a transparent synthetic resin.

The black matrix 102 is on the opposite insulating substrate 100 to block light that is incident in a region in which liquid crystals are incontrollable. Thus, it may be possible to improve the contrast ratio of the display device.

The color filter 104 is on the opposite insulating substrate 100, on which the black matrix 102 is formed, to transmit color light having a wavelength corresponding to a color. The color filter 104 corresponds to a pixel electrode 112 of the array substrate 180.

The common electrode 106 is on the opposite insulating substrate 100 on which the black matrix 102 and the color filter 104 are formed. The common electrode 106 includes a transparent conductive material. Examples of the transparent conductive material include indium tin oxide (ITO), indium zinc oxide (IZO), amorphous indium tin oxide (a-ITO), and combinations thereof.

A spacer (not shown) may be interposed between the array substrate 180 and the opposite substrate 170 to maintain a distance between the array substrate 180 and the opposite substrate 170. The spacer may be a bead spacer, a ball spacer, or a column spacer.

A liquid crystal layer 108 is interposed between the array substrate 180 and the opposite substrate 170. When a voltage difference occurs between the common electrode 106 and the pixel electrode 112, an electric field is formed between the common electrode 106 and the pixel electrode 112. The orientations of the liquid crystals of the liquid crystal layer 108 vary in response to the electric field formed between the common electrode 106 and the pixel electrode 112. Thus, light transmittance of the liquid crystal layer 108 is changed and an image having a gray-scale is displayed.

A sealant (not shown) may seal the liquid crystal layer 108 between the array substrate 180 and the opposite substrate 170.

Accordingly, the occurrence of defects in the array substrate 180 of the display device of FIG. 21 may be decreased and the manufacturing process of the array substrate 180 may be simplified. Thus, the image display quality of the display device may be improved and the manufacturing cost of the display device may be decreased.

What is claimed is:

1. A wiring structure comprising;
a substrate;
a copper oxide layer having 16˜39 at % oxygen on the substrate; and
a copper layer on the copper oxide layer.

2. The wiring structure of claim 1, wherein the copper oxide layer has a thickness of 10-1000 Å.

3. The wiring structure of claim 2, wherein the copper layer has a thickness of 300-20000 Å.

4. The wiring structure of claim 3, wherein the copper layer and the copper oxide layer further comprise a alloy element less than 10 wt %.

5. The wiring structure of claim 4, wherein the alloy element selects from the group of Ag, Ni, Mg, Zr, N.

6. The wiring structure of claim 2, wherein the copper layer and the copper oxide layer further comprise an alloy element less than 10 wt %.

7. The wiring structure of claim 6, wherein the alloy element selects from the group of Ag, Ni, Mg, Zr, N.

8. The wiring structure of claim 1, wherein the copper layer has a thickness of 300-20000 Å.

9. The wiring structure of claim 8, wherein the copper layer and the copper oxide layer further comprise a alloy element less than 10 wt %.

10. The wiring structure of claim 9, wherein the alloy element selects from the group of Ag, Ni, Mg, Zr, N.

11. The wiring structure of claim 1, wherein the copper layer and the copper oxide layer further comprise a alloy element less than 10 wt %.

12. The wiring structure of claim 11, wherein the alloy element selects from the group of Ag, Ni, Mg, Zr, N.

13. A thin film transistor, comprising:
a gate electrode comprising a copper layer and copper oxide layer on an insulating substrate;
a semiconductor layer on the gate electrode;
a source and drain electrode on the semiconductor layer

14. The thin film transistor of claim 13, the copper oxide layer having an 16 at %˜39 at % oxygen.

15. The thin film transistor of claim 14, the thickness of the copper oxide layer is 10-1000 Å.

16. The thin film transistor of claim 15, wherein the copper layer has a thickness of 300-20000 Å.

17. The thin film transistor of claim 16, wherein the copper layer and the copper oxide layer further comprise an alloy element less than 10 wt %.

18. The wiring structure of claim 17, wherein the alloy element selects from the group of Ag, Ni, Mg, Zr, N.

19. The thin film transistor of claim 13, the thickness of the copper oxide layer is 10-1000 Å.

20. The thin film transistor of claim 13, wherein the copper layer has a thickness of 300-20000 Å.

21. The thin film transistor of claim 13, wherein the copper layer and the copper oxide layer further comprise an alloy element less than 10 wt %.

22. The wiring structure of claim 21, wherein the alloy element selects from the group of Ag, Ni, Mg, Zr, N.

23. A method of forming a wiring structure comprising;
forming a copper oxide layer having 16˜39 at % oxygen on a substrate; and
forming a copper layer on the copper oxide layer.

24. A method forming a thin film transistor comprising;
forming a gate electrode with copper layer and copper oxide layer;
forming a semiconductor layer on the gate electrode;
forming a source and drain electrode on the semiconductor layer.
